(19) United States
(12) Patent Application Publication
(10) Pub. No.: US 2024/0429274 A1
(43) Pub. Date: Dec. 26, 2024

(54) NANOSHEET DEVICE

(71) Applicant: IMEC VZW, Leuven (BE)

(72) Inventors: Geert Hellings, Halle (BE); Pieter Schuddinck, Nieuwerkerken (Aalst) (BE)

(21) Appl. No.: 18/753,824

(22) Filed: Jun. 25, 2024

(30) Foreign Application Priority Data
Jun. 26, 2023 (EP) 23181483.1

(51) Int. Cl. H01L 29/06; H01L 27/092; H01L 29/417; H01L 29/423; H01L 29/775; H01L 29/786

(52) U.S. Cl. CPC H01L 29/0649; H01L 27/0928; H01L 29/0673; H01L 29/41775; H01L 29/42392; H01L 29/775; H01L 29/78696

(57) ABSTRACT

Provided herein is a nanosheet device that includes a first and a second transistor structure, each comprising a respective source region, drain region, and channel region extending between the respective source and drain regions, a dielectric wall, a gate structure, and a gate spacer, wherein the channel region of the first transistor structure includes a first set of vertically stacked channel layers, wherein each channel layer of the first set of vertically stacked channel layers has an inward facing surface contacting a first side surface of the dielectric wall, and wherein the channel region of the second transistor structure includes a second set of vertically stacked channel layers, and wherein each channel layer of the second set of vertically stacked channel layers has an inward facing surface contacting a second side surface, opposite to the first side surface, of the dielectric wall

### CROSS-REFERENCE TO RELATED APPLICATIONS

The present application is a non-provisional patent application claiming priority to European Patent Application No. EP 23181483.1, filed on Jun. 26, 2023, the contents of which are hereby incorporated by reference.

### FIELD OF THE DISCLOSURE

The present disclosure relates to nanosheet devices.

### BACKGROUND

In an effort to provide even more area-efficient circuit designs, non-planar transistor devices have been developed, such as the FinFET and the horizontal or lateral nanosheet FET (NSHFET). In a NSHFET a number of nanosheets may be stacked in the vertical dimension to provide an increased drive current with a reduced horizontal footprint. A more recent NSHFET design is the so-called forksheet device. The forksheet device comprises two transistors of complementary conductivity types comprising respective sets of vertically stacked channel nanosheets on opposite sides of a vertically oriented dielectric wall. The transistors are controlled by a respective gate stack separated by the dielectric wall. The dielectric wall may be formed before gate patterning and source/drain epitaxy (“S/D epi”), and may facilitate individual processing of N- and P-type source/drain regions and gate stacks for the two transistors. The forksheet device thus enables more aggressive scaling of the N-to-P spacing.

However, nanosheet devices in general, and forksheet devices in particular, still face challenges related to downsizing, e.g., avoiding N/P merging over the dielectric wall and/or reducing the relatively large number of etchback steps during replacement metal gate (“RMG”), formation. Further, the relatively narrow wall normally present in forksheet devices complicates fin formation upon nanosheet stack etching.

### SUMMARY

The present disclosure provides an overall improved nanosheet device.

The present disclosure provides a nanosheet device associated with a reduced epi source/drain and gate metal shorting.

The present disclosure provides a nanosheet device having a smaller footprint area.

The present disclosure provides a nanosheet device having a smaller capacitance at cell level.

The present disclosure provides a nanosheet device having a reduced parasitic series resistance.

The present disclosure provides a nanosheet device that is easier to manufacture.

Further and alternative benefits of the present disclosure may be understood from the following.

According to a first aspect of the present disclosure there is provided a nanosheet device comprising a first and a second transistor structure, each comprising a respective source region, drain region, and channel region extending between the respective source and drain regions, a dielectric wall, a gate structure, and a gate spacer, wherein the channel region of the first transistor structure comprises a first set of vertically stacked channel layers, wherein each channel layer of the first set of vertically stacked channel layers has an inward facing surface contacting a first side surface of the dielectric wall, and wherein the channel region of the second transistor comprises a second set of vertically stacked channel layers, wherein each channel layer of the second set of vertically stacked channel layers has an inward facing surface contacting a second side surface, opposite to the first side surface, of the dielectric wall, wherein a top portion of the gate structure is arranged above a top surface of the dielectric wall, and wherein the material of the gate spacer is also arranged at a third and a fourth side surface of the dielectric wall, the third and the fourth side surface being transverse to the first and the second side surface of the dielectric wall.

Thus, the dielectric wall is enclosed by the first and second set of vertically stacked channel layers, the gate structure, and the gate spacer. This in contrast to previous forksheet devices, in which the dielectric wall is present also in the S/D region.

This geometrical configuration of layers/components facilitates easier manufacturing since the dielectric wall may be made relatively wide without compromising the footprint area of the nanosheet device. That is, the distance between the two vertically stacked channel layers may be relatively large. The “width” of the dielectric wall is thus understood as being (the closest) distance between the first and the second set of vertically stacked channel layers, i.e., along a horizontal extension transverse to the direction along which electron/hole transport takes place in one of the nanosheets.

The present nanosheet device further facilitates survival of the dielectric wall material during front end of line, FEOL, processing.

Further, previous forksheet devices typically include a relatively high dielectric wall to avoid n/p merging over the wall, thus resulting in a higher gate. This may be avoided in the embodiments of the present disclosure.

Spatial terms such as “longitudinal” and “vertical”, as used herein, are to be understood in relation to a substrate on which the transistor structure is to be placed or fabricated on, wherein “longitudinal” denotes an orientation or direction parallel to a main plane of extension of the substrate and “vertical” denotes an orientation or direction normal to the main plane of extension of the substrate. Throughout, the term “longitudinal” refers to an extension of the channel in which charge transport is to take place if not stated otherwise, i.e., along the channel. Correspondingly, relative spatial terms such as, “upper”, “lower”, “top”, “bottom”, “above”, “under”, “underneath”, “below”, are to be understood in relation to the substrate, as seen along the vertical/normal direction.

The terms “frontside” and “backside” of a substrate, on which the nanosheet device is arranged, refer respectively to the two mutually opposite (main) sides of the substrate, wherein the frontside is the side of the substrate on which the transistor (and any further active devices) is formed, and wherein the backside is the opposite side of the substrate.

The term “source/drain” as used herein is to be understood as a source or a drain. Hence, “source/drain region” may either be a source region or a drain region.

The top surface of the dielectric wall may be flush with a top surface of the channel region of the first transistor structure and with a top surface of the channel region of the second transistor structure. In such embodiments, the top surface of the dielectric wall is substantially on the same vertical level as the top surface of the channel region of the first and the second transistor structure. Compared to previous forksheet devices where the dielectric wall vertically protrudes above the top surface of the channel region, the embodiments of the present disclosure facilitate reduction of the vertical extension of the nanosheet device. This may further reduce the height of the gate structure without compromising with the electrical properties of the device.

In some embodiments, a length of the channel region of the first transistor structure and a length of the channel region of the second transistor structure correspond to a length of the gate structure.

The lengths referred to above are to be understood as lengths taken along the longitudinal extension.

In some examples, a distance between the third side surface of the dielectric wall and the fourth side surface of the dielectric wall corresponds to the length of the gate structure. In such examples, the length, i.e., the longitudinal extension, of the dielectric wall substantially equals the length, i.e., the longitudinal extension, of the gate structure.

In some embodiments, the dielectric wall substantially has the same extension as the channel region.

In some examples, a bottom surface of the dielectric wall is arranged above a shallow trench isolation, STI, layer.

In some examples, the dielectric wall and the STI layer are formed by a same material. This renders a simpler manufacturing of the nanosheet device since the dielectric wall can be formed at the same step as the STI.

In some examples, one or more of the dielectric wall and the STI layer comprise an oxide or nitride material.

In some examples, each one of the first set of vertically stacked channel layers and the second set of vertically stacked channel layers comprises three or more stacked channel layers.

Such a nanosheet device may thus provide for stacking a larger number of channel layers compared to previous forksheet devices. This is because the dielectric wall in general is wider than in previous forksheet devices. This further facilitates reducing the footprint of the nanosheet device while maintaining or increasing the number of logic gates per area unit of the substrate.

In some examples, a shortest distance between the first and the second side surface of the dielectric wall is at least 50% of a width of each one of the first set of vertically stacked first channel layers and the second set of vertically stacked second channel layers. This may prevent epi and gate metal shorting across in n/p devices. Further, (parasitic) capacitance between gate and drain may be reduced. Such a 50% figure provides a reasonable tradeoff in terms of performance and ease/difficulty with regard to lithography, etching and nanosheet release.

In some examples, a shortest distance between the first side surface and the second side surface of the dielectric wall is at least 10 nm. This can facilitate manufacturing compared to devices having dielectric walls of smaller lateral dimensions.

In some examples, the first transistor structure comprises an n-FET type material and the second transistor structure comprises a p-FET type material. This is a common configuration of a forksheet or similar nanosheet device, thus enabling substantial scaling with regard to N-to-P spacing, which may be substantially similar to the width of the dielectric wall. The n-FET/p-FET type material is thus present in the S/D region (in the form of epi layers) of the transistor structure in question.

Further applications of the embodiments described herein are provided in the detailed description given below. However, it should be understood that the detailed description and specific examples, while indicating various embodiments of the present disclosure, are given by way of illustration only, since various changes and modifications within the scope of the present disclosure will become apparent to those skilled in the art from this detailed description.

Thus, it is to be understood that the present disclosure is not limited to the particular component parts of the device described or acts of the methods described as such devices and methods may vary. It is also to be understood that the terminology used herein is for purpose of describing particular embodiments only and is not intended to be limiting. It must be noted that, as used in the specification and the appended claims, the articles “a,” “an,” “the,” and “said” are intended to mean that there are one or more of the elements unless the context clearly dictates otherwise. Thus, for example, reference to “a unit” or “the unit” may include several units, and the like. Furthermore, the words “comprising”, “including”, “containing” and similar wordings does not exclude other elements or steps.

### BRIEF DESCRIPTION OF THE FIGURES

The above, as well as additional objects, features, and benefits, may be understood through the following illustrative and non-limiting detailed description, with reference to the appended drawings. In the drawings like reference numerals will be used for like elements unless stated otherwise.

FIG. 1 schematically depicts a prior art forksheet device, according to an example embodiment.

FIG. 2. schematically depicts a vertical-transversal cross-sectional profile of a nanosheet device, according to an example embodiment.

FIG. 3A schematically shows a top view of a nanosheet device, according to an example embodiment.

FIG. 3B, FIG. 3C, and FIG. 3D schematically show vertical-transversal cross-sectional profiles along the nanosheet device of FIG. 3A.

FIG. 4A schematically shows a top view of a nanosheet device, according to an example embodiment.

FIG. 4B schematically shows a vertical-longitudinal cross-sectional profile of the nanosheet device of FIG. 4A.

All the figures are schematic, not necessarily to scale, and generally only show parts to elucidate example embodiments, wherein other parts may be omitted or merely suggested.

### DETAILED DESCRIPTION

In the following detailed description, all references to specific materials and dimensions are included by way of example only, and none of these citations are to be construed as limitations of the protection scope.

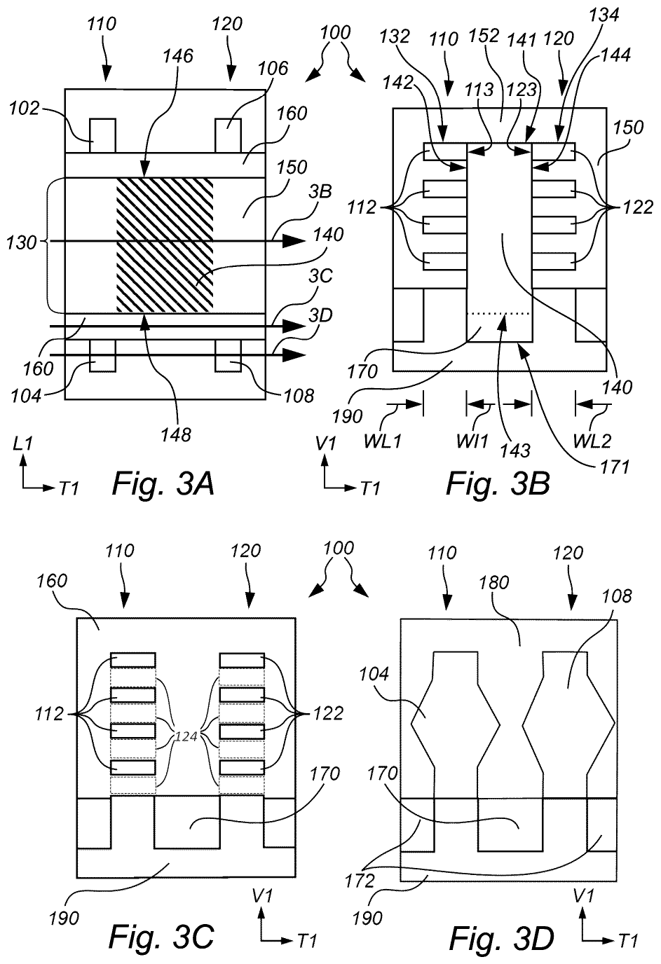

The embodiments of the present disclosure will now be described more fully with reference to the accompanying drawings, in which various example embodiments are shown. The concepts of the present disclosure may, however, be embodied in many different forms and should not be construed as limited to the specific embodiments set forth herein; rather, these embodiments are provided for thoroughness and completeness, and to fully convey the scope of the present disclosure to the skilled person. FIG. 3A schematically shows a top view of a nanosheet device 100 (in longitudinal L1 versus transversal T1 direction). Arrows 3B, 3C and 3D in FIG. 3A refer to cross sections spanned in vertical Vi and transversal T1 extension of the nanosheet device. These cross sections are schematically depicted in FIGS. 3B, 3C and 3D, i.e., the figures are numbered according to the arrows 3B, 3C, and 3D in FIG. 3A.

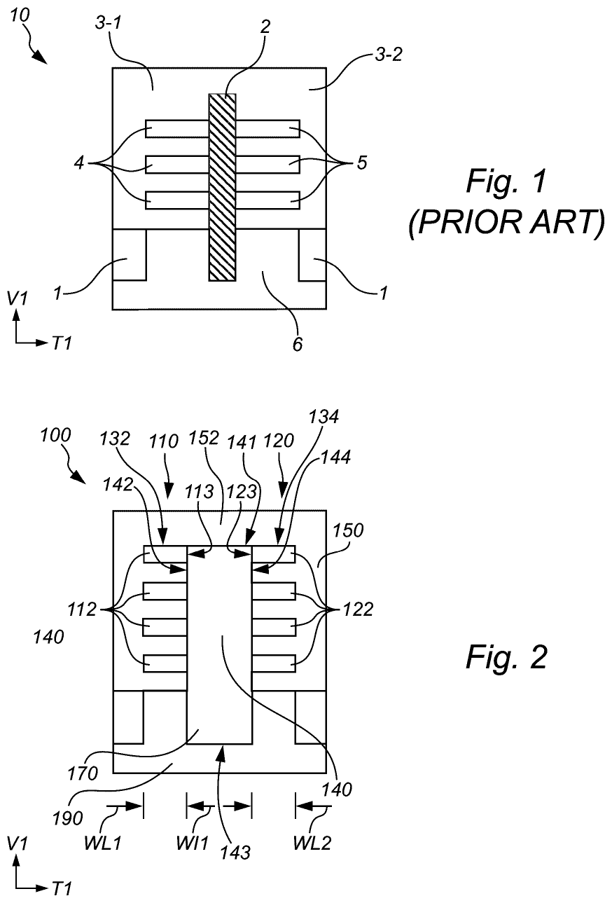

FIG. 1 (prior art) schematically depicts a previous forksheet device. The term forksheet device refers to a device 10 comprising a first 4 and a second 5 set of vertically stacked channel layers (nanosheets) formed on opposite sides of a vertically oriented dielectric wall 2. Each channel layer of the first set 4 of vertically stacked channel layers has an inner edge contacting a first side of the dielectric wall 2 and each channel layer of the second set 5 of vertically stacked channel layers have an inner edge contacting a second side of the dielectric wall 2, opposite the first side. The forksheet device 10 comprises a first gate stack 3-1 surrounding the first set 4 of vertically stacked channel layers and contacting the first side of the dielectric wall 2, and a second gate stack 3-2 surrounding the second set 5 of vertically stacked channel layers and contacting the second side of the dielectric wall 2. The first transistor may comprise an N-type gate stack and the second transistor may comprise a P-type gate stack, or vice versa. Alternatively, the first and the second transistor may both comprise N-type gate stacks, or P-type gate stacks. Hence, four combinations of gate stack types may be possible within the scope of the claims.

A shallow trench isolation (STI) region 1 is typically present on respective transversal side of the gate stacks, i.e., trenched in the substrate on which the transistor is arranged. The material type of the STI region may be different to the material of the dielectric wall 2.

Forming of the forksheet device 10 may be done according to a process flow known by a person skilled in the art, which may comprise forming a first set 4 of vertically stacked channel layers and a second set 5 of vertically stacked channel layers by a separating trench extending into the base portion thus forming the two vertically stacked channel layers. The trench may thereafter be filled with dielectric material to form the dielectric wall 2. A first gate stack 3-1, surrounding the first set 4 of vertically stacked channel layers and contacting the first side of the dielectric wall 2, is formed, as well as a second gate stack 3-2 surrounding the second set 5 of vertically stacked of channel layers and contacting the second side of the dielectric wall.

FIG. 2 schematically depicts a cross-section of a nanosheet device according to the present disclosure, emphasizing structural differences relative to the embodiment depicted in FIG. 1. FIG. 2 depicts the same view as the view shown in FIG. 3B and will thus be further explained below.

More specific to the present disclosure and the terminology set forth in the claims, the nanosheet device 100 comprises a first 110 and a second 120 transistor structure. As the first 110 and the second 120 transistor structures generally are geometrically structurally similar, reference numerals may occasionally only be indicated in the drawings for one of the transistor structures 110, 120, e.g., for the first transistor structure 110. Each of the first 110 and the second 120 transistor structure comprises a source region 104, 108, a drain region 102, 106, and a channel region 130 extending between the source 104, 108 and the drain 102, 106 region. Hence, the channel region 130 may be viewed as an ordinary depletion region/zone in which the amount of longitudinally moving charge carriers (electron or holes) per unit of time is controlled by a voltage or potential field applied on the channel region 130 by the gate.

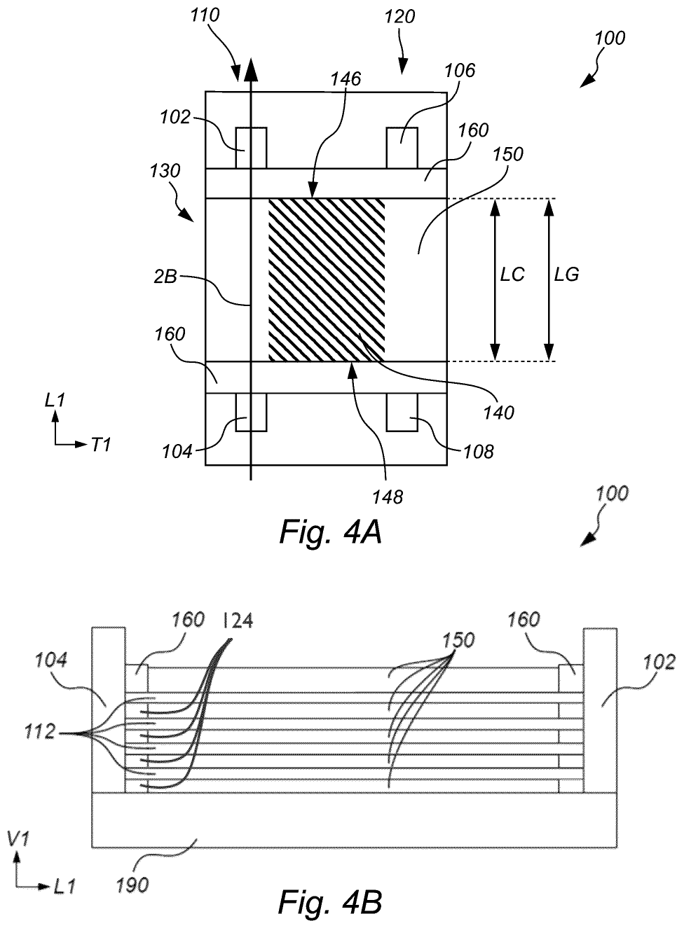

The nanosheet device 100 further comprises a dielectric wall 140. The dielectric wall 140 is best viewed in FIG. 3B. A lateral location, i.e., in an L1-T1 (longitudinal-transversal) plane of the dielectric wall 140 is viewed as a dashed region in FIG. 3A and FIG. 4A. This location is further discussed thoroughly below.

The nanosheet device 100 further comprises a gate structure 150. With reference to FIGS. 3A and 4A the gate structure 150 obscures the dielectric wall 140 (dashed region) when viewed from above.

The gate structure 150 may be different for the first 110 and the second 120 transistor structure, as appreciated by the skilled person, as a consequence of the possibly differing types of nanosheet stacks (N-type, P-type, etc.) of the different transistor structures 110, 120. FIG. 3C shows a cross-sectional profile of the nanosheet device 100 across the gate spacer 160, i.e., in the V1-T1 (vertical-transversal) plane. At this cross section the first 112 and the second 122 set of vertically stacked channel layers are transversally embedded in the gate spacer 160 and the inner spacers 124 (which are present in between the nanosheets)

The gate spacer 160 comprises sidewall spacer material on top of the nanosheet stack in contact with the gate structure and thereby providing isolation between the source/drain contacts and the gate contact and the gate spacer 160 also comprises material arranged at a third 146 and a fourth 148 side surface of the dielectric wall 140.

The channel region 130 of the first transistor structure 110 further comprises a first set 112 of vertically stacked channel layers, i.e., stacked along the vertical extension V1. Each channel layer of the first set 112 of vertically stacked channel layers has an inward facing surface 113 contacting a first side surface 142 of the dielectric wall 140.

The channel region 130 of the second transistor structure 120 further comprises a second set 122 of vertically stacked channel layers, stacked along the vertical extension Vi. Each channel layer of the second set 122 of vertically stacked channel layers has an inward facing surface 123 contacting a second side surface 144, opposite to the first side surface, of the dielectric wall 140. The wording “opposite” is to be understood as “substantially opposite”, as there by way of example may be significant local variations at the surfaces due to the small dimensions considered for the nanosheet device. This applies to other surfaces throughout this disclosure, as readily appreciated by the skilled person. As is further understood, corners may be rounded/blunt for the same reason.

Atop portion 152 of the gate structure 150 is arranged above a top surface 141 of the dielectric wall 140.

The gate spacer 160 (material of the gate spacer 160) is arranged at a third 146 and a fourth 148 side surface of the dielectric wall 140. The third 146 and the fourth 148 side surface is thus transverse to the first 142 and the second 144 side surface of the dielectric wall 140.

The top surface 141 of the dielectric wall 140 may be flush with a top surface 132 of the channel region 130 of the first transistor structure 110 and with a top surface 134 of the channel region 130 of the second transistor structure 120.

A length LC of the channel region 130, i.e., a channel length LC of the first transistor structure 110 and a length LC of the channel region 130 of the second transistor structure 120 may correspond to a length LG of the gate structure 150. The lengths LG, LC thus refer to a distance along the longitudinal extension L1. This is best viewed in FIGS. 4A-B. It is to be understood that the correspondence is not necessarily exact. This since precise manufacturing obscures exact manufacture of components of transistors at the present length scales involved.

A distance between the third side surface 146 of the dielectric wall 140 and the fourth side surface 148 of the dielectric wall may correspond to the length LG of the gate structure 150. A bottom surface 143 of the dielectric wall 140 may be arranged above a shallow trench isolation, STI, layer 170.

The dielectric wall 140 and the STI layer 170 may be formed by a same material. The dielectric wall 140 and the STI layer 170 may be formed by a same material during the same processing step. In this case, the bottom surface 143 of the dielectric wall 140 manifestly coincides with a bottom surface 171 of the STI layer 170.

One or more of the dielectric wall 140 and the STI layer 170 may comprise an oxide or nitride material. Example materials in connection hereto may be SiO₂ (silicon oxide), SiN, Si₃N₄ (silicon nitride), SiOₓN_{y} (silicon oxynitride) and Si.

Each one of the first set of vertically stacked channel layers 112 and the second set of vertically stacked channel layers 122 may comprise three or more stacked channel layers 112, 122. However, any adequate number of stacked channel layers may be possible within the scope of the claims. By way of example, and as depicted in some of the appended drawings, the first 112 and the second 122 set of vertically stacked channel layers 122 may comprise four stacked channel layers 112, 122.

A shortest distance WI1 between the first 142 and the second 144 side surface of the dielectric wall may be at least 50% of a width WL1, WL2 of each one of the first set 112 of vertically stacked first channel layers and the second set 122 of vertically stacked second channel layers.

A shortest distance between the first side surface 142 and the second side surface 144 of the dielectric wall may be at least 10 nm. For example, the shortest distance between the first side surface 142 and the second side surface 144 of the dielectric wall can be in the range 5-25 nm.

The first transistor structure 110 may comprise an n-FET type material and the second transistor structure 120 may comprise a p-FET type material. The opposite is manifestly also possible. Further, the first transistor structure 110, or, more correctly the two epi layers constituting the longitudinal ends of respective nanosheet stack, may be doped thereby defining an n-FET type or p-FET type transistor. For example, the vertically stacked channel layers 112, 122 themselves may be undoped, although at least light doping of these is possible. As familiar to those skilled in the art a possibly doped nanosheet stack may exhibit differing dopant profiles among the nanosheets of the stack of nanosheets.

FIG. 3D schematically shows a cross-sectional profile taken at arrow 3D in FIG. 3A. This cross-sectional profile schematically depicts a source/drain region of respective set of vertically stacked channel layers 112, 122. The first set of vertically stacked layers 112 may be longitudinally terminated by an N-epi layer 102, 104 of respective side of the channel region 130, and the second set of vertically stacked layers 122 may be longitudinally terminated by a P-epi layer 106, 108 of respective side of the channel region 130. The N-epi layer 102, 104 and the P-epi layer 106, 108 may be enclosed by a dielectric layer 180 in the V1-T1 (vertical-transversal) plane. For example, the dielectric layer 180 may be a first inter layer dielectric (sometimes referred to as an ILDO) layer 180, located above an STI layer 170 comprising SiO₂. The depicted diamond/rhombic geometry of the N- and P-epi layers 104, 108 may originate from crystalline growth of these materials at the S/D region, and thus depends on the Miller indices (e.g., 110, 111, etc.) of these materials relative to the surface they are grown on.

To further facilitate understanding of the nanosheet device 100 described above, FIG. 4B shows a cross-sectional profile along the longitudinal extension L1 of the nanosheet device 100. The cross-sectional profile is taken along the arrow 4B in FIG. 4A. FIGS. 4A and 4B are thus clearly understood from the above description.

Accordingly, and in summary, in some variants discussed above, there has been described a nanosheet device 100 having a first 112 and a second 122 set of vertically stacked channel layers separated by a dielectric wall 140. The dielectric wall 140 is geometrically/physically enclosed between the first 112 and the second 122 set of vertically stacked channel layers, the gate structure 150 and the gate spacer 160, providing a nanosheet device 100 that may include further vertically aligned nanosheets in each channels stack 112, 122, thus increasing the number of logic operations per area unit of the nanosheet device 100. Other benefits are a smaller capacitance at cell level, reduction of parasitic series resistance, avoiding n/p merging over the dielectric wall, and reducing the relatively large number of etchback steps during replacement metal gate, RMG, formation.

The person skilled in the art realizes that the scope of the present disclosure is not limited to the specific embodiments described above. On the contrary, many modifications and variations are possible within the scope of, e.g., the appended claims. Variations to the disclosed embodiments can be understood and effected by the skilled person in practicing the claimed subject matter, from a study of the drawings, the disclosure, and the appended claims.

While the subject matter of the present disclosure has been illustrated and described in detail in the drawings and foregoing description, such illustration and description are to be considered illustrative or exemplary and not restrictive. Other variations to the disclosed embodiments can be understood and effected by those skilled in the art from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to provide some benefit.

Unless specifically specified, the description of a layer being present, deposited or produced ‘on’ another layer or substrate, includes the options of: (i) the layer being present, produced or deposited directly on, i.e. in physical contact with, the other layer or substrate, and (ii) the layer being present, produced or deposited on one or a stack of intermediate layers between the layer and the other layer or substrate

In the claims as well as in the description of this disclosure, the word “comprising” does not exclude other elements or steps and the indefinite article “a” or “an” does not exclude a plurality. A single element may fulfill the functions of several entities or items recited in the claims. The mere fact that certain measures are recited in the mutual different dependent claims does not indicate that a combination of these measures cannot be used in an implementation to provide some benefit.

While various embodiments of the present disclosure have been described above, it should be understood that they have been presented by way of example only, and not limitation. Numerous changes to the disclosed embodiments can be made in accordance with the disclosure herein without departing from the spirit or scope of the present disclosure. Thus, the breadth and scope of the present present disclosure should not be limited by any of the above described embodiments.

Although the embodiments described herein have been illustrated and described with respect to one or more implementations, equivalent alterations and modifications will occur to others skilled in the art upon the reading and understanding of this specification and the annexed drawings. In addition, while a particular feature of the present disclosure may have been disclosed with respect to only one of several implementations, such feature may be combined with one or more other features of the other implementations as may be desired for any given or particular application.

What is claimed is:

1. A nanosheet device comprising:
a first transistor structure comprising a source region, a drain region, and a channel region extending between the source and the drain region;
a second transistor structure comprising a source region, a drain region, and a channel region extending between the source and the drain region;
a dielectric wall;
a gate structure; and
a gate spacer,
wherein the channel region of the first transistor structure comprises a first set of vertically stacked channel layers, wherein each channel layer of the first set of vertically stacked channel layers has a respective inward facing surface contacting a first side surface of the dielectric wall, and wherein the channel region of the second transistor structure comprises a second set of vertically stacked channel layers, wherein each channel layer of the second set of vertically stacked channel layers has a respective inward facing surface contacting a second side surface, opposite to the first side surface, of the dielectric wall,
wherein a top portion of the gate structure is arranged above a top surface of the dielectric wall, and
wherein a material of the gate spacer is arranged at a third side surface and a fourth side surface of the dielectric wall, the third and the fourth side surfaces being transverse to the first and the second side surface of the dielectric wall.

2. The nanosheet device of claim 1, wherein the top surface of the dielectric wall is flush with a top surface of the channel region of the first transistor structure and with a top surface of the channel region of the second transistor structure.

3. The nanosheet device of claim 1, wherein a length of the channel region of the first transistor structure and a length of the channel region of the second transistor structure correspond to a length of the gate structure.

4. The nanosheet device of claim 1, wherein a distance between the third side surface of the dielectric wall and the fourth side surface of the dielectric wall corresponds to a length of the gate structure.

5. The nanosheet device of claim 1, wherein a bottom surface of the dielectric wall is arranged above a shallow trench isolation layer.

6. The nanosheet device of claim 5, wherein the dielectric wall and the STI layer are formed of the same material.

7. The nanosheet device of claim 6, wherein the dielectric wall and the STI layer comprise an oxide material.

8. The nanosheet device of claim 1, wherein the dielectric wall and the STI layer comprise a nitride material.

9. The nanosheet device of claim 1, wherein the first set of vertically stacked channel layers comprises three or more stacked channel layers and wherein the second set of vertically stacked channel layers comprises three or more stacked channel layers.

10. The nanosheet device of claim 1, wherein a shortest distance between the first side surface of the dielectric wall and the second side surface of the dielectric wall is at least 50% of a width of one of the first set of vertically stacked first channel layers.

11. The nanosheet device of claim 1, wherein a shortest distance between the first side surface of the dielectric wall and the second side surface of the dielectric wall is at least 50% of a width of one of the second set of vertically stacked second channel layers.

12. The nanosheet device of claim 11, wherein a shortest distance between the first side surface of the dielectric wall and the second side surface of the dielectric wall is at least 50% of a width of one of the first set of vertically stacked first channel layers.

13. The nanosheet device of claim 1, wherein a shortest distance between the first side surface of the dielectric wall and the second side surface of the dielectric wall is at least 10 nm.

14. The nanosheet device of claim 13, wherein a shortest distance between the first side surface of the dielectric wall and the second side surface of the dielectric wall is at least 50% of a width of one of the first set of vertically stacked first channel layers.

15. The nanosheet device of claim 14, wherein a bottom surface of the dielectric wall is arranged above a shallow trench isolation layer.

16. The nanosheet device of claim 13, wherein a shortest distance between the first side surface of the dielectric wall and the second side surface of the dielectric wall is at least 50% of a width of one of the second set of vertically stacked second channel layers.

17. The nanosheet device of claim 16, wherein a bottom surface of the dielectric wall is arranged above a shallow trench isolation layer.

18. The nanosheet device of claim 16, wherein a shortest distance between the first side surface of the dielectric wall and the second side surface of the dielectric wall is at least 50% of a width of one of the first set of vertically stacked first channel layers.

19. The nanosheet device of claim 18, wherein a bottom surface of the dielectric wall is arranged above a shallow trench isolation layer.

20. The nanosheet device of claim 1, wherein the first set of vertically stacked channel layers comprises an n-FET type material and wherein the second set of vertically stacked channel layers comprises a p-FET type material.
